(19) United States
(12) Patent Application Publication
(10) Pub. No.: US 2007/0126036 A1
(43) Pub. Date: Jun. 7, 2007

(54) Semiconductor device and semiconductor device manufacturing method

(75) Inventors: Hiroyuki Ohta, Kawasaki (JP); Akiyoshi Hatada, Kawasaki (JP); Yosuke Shimamune, Kawasaki (JP); Akira Katakami, Kawasaki (JP); Naoyoshi Tamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/393,656

(22) Filed: Mar. 31, 2006

(30) Foreign Application Priority Data
Dec. 2, 2005 (JP) JP2005-349490

(51) Int. Cl. H01L 29/76

(52) U.S. Cl. 257/288

(57) ABSTRACT

A semiconductor device is configured so that there is formed a stressor film 4 covering the first field effect transistor and the second field effect transistor, formed with openings from which the originating area and the terminating area of each of the first field effect transistor and the second field effect transistor are partially exposed, and applying a stress to at least an area extending from the vicinity of the originating area to the vicinity of the terminating area of each of the first field effect transistor and the second field effect transistor, and that a height of a first gate electrode 3 (3A) in a direction substantially perpendicular to a first insulating layer is set different from a height of a second electrode 3 (3B) in the direction substantially perpendicular to a second insulating layer.

### BACKGROUND OF THE INVENTION

The invention relates to a CMOS semiconductor device.

A variety of proposals (refer to Patent documents 1 through 3) are made in order to increase a process margin when manufacturing a semiconductor device or to improve an electric characteristic of the semiconductor device.

Especially, recognition acquired over the recent years is that element performance is changed by applying a stress to a semiconductor device. It is generally known that an NMOS semiconductor device gets improvement of an electron mobility due to a stress acting in a direction of stretching (a direction in which an interval between atoms structuring a crystal expands) within a plane parallel with a substrate of the semiconductor device. On the other hand, it is known that a PMOS semiconductor device gets improvement of a hole mobility due to a stress acting in a direction of compressing (a direction in which the interval between atoms structuring the crystal shrinks) within the plane parallel with the substrate of the semiconductor device.

A practice is therefore such that a film generating the stress acting in the stretching direction parallel to the substrate is attached to the surface (e.g., a layer above a cover film) of the NMOS semiconductor device. Conducted further is a process of attaching the surface of the PMOS semiconductor device with a film generating a stress acting in a direction of compressing in the direction parallel with the substrate.

The CMOS semiconductor device is, however, constructed by combining the NMOS semiconductor device and the PMOS semiconductor device with each other. Hence, the improvement of the element performance of the CMOS semiconductor device requires separately employing the stress acting in the direction of stretching within the plane parallel with the substrate and the stress acting in the direction of compressing. Due to such a separate use of these stresses, however, the attachment of the different types of films to the surfaces of the NMOS transistor portion and the PMOS transistor portion of the CMOS semiconductor device, leads to intricacy of the manufacturing process. Moreover, it is not easy to form such a complicated film while keeping a predetermined dimensional accuracy and positional accuracy.
[Patent document 1] Japanese Patent Application Laid-Open Publication No. 2002-217307
[Patent document 2] Japanese Patent Application Laid-Open Publication No. 2000-77540
[Patent document 3] Japanese Patent Application Laid-Open Publication No. 4-32260

### SUMMARY OF THE INVENTION

It is an object of the invention to provide a technology of improving an electric characteristic by controlling the stress applied to the CMOS semiconductor device with a simple manufacturing process.

The invention adopts the following means in order to solve the problems. Namely, the invention is a semiconductor device including a first field effect type transistor of a first conductivity type and a second field effect type transistor of a second conductivity type that are provided on a semiconductor substrate,
the first field effect type transistor comprising a first gate electrode, a first insulating layer under the first gate electrode, a conductive layer of the second conductivity type for forming a first conductive path of the first conductivity type under the first insulating layer, a first conductivity type originating area that is formed at one end of a second conductivity type area which should become the first conductive path, and that should become an originating point of the first conductive path, and a first conductivity type terminating area that is formed at the other end of the second conductivity type area and that should become a terminating point of the first conductive path, the second field effect type transistor comprising a second gate electrode, a second insulating layer under the second gate electrode, a conductive layer of the first conductivity type for forming a second conductive path of the second conductivity type under the second insulating layer, a second conductivity type originating area that is formed at one end of a first conductivity type area which should become the second conductive path, and that should become an originating point of the second conductive path, and a second conductivity type terminating area that is formed at the other end of the first conductivity type area and that should become a terminating point of the second conductive path, wherein there is formed a stressor film covering the first field effect transistor and the second field effect transistor, formed with openings from which the originating area and the terminating area of each of the first field effect transistor and the second field effect transistor are partially exposed, and applying a stress to at least an area extending from the vicinity of the originating area to the vicinity of the terminating area of each of the first field effect transistor and the second field effect transistor, and a height of the first gate electrode in a direction substantially perpendicular to the semiconductor substrate is set different from a height of the second electrode in the direction substantially perpendicular to the semiconductor substrate.

According to the invention, it is possible to improve the electric characteristic by controlling the stress applied to the CMOS semiconductor device with such a simple manufacturing process as to differentiate the gate heights in the NMOS transistor and in the PMOS transistor.

### BRIEF DESCRIPTION OF THE DRAWINGS

FIG. 1A is a view showing a gate height and a film thickness of a stressor film;

FIG. 1B is a view showing a relationship between influence of the stressor film upon a stress of a substrate and the gate height;

FIG. 2 is a detailed sectional view showing a PMOS transistor portion of a semiconductor device according to a first embodiment of the invention;

FIG. 3 is a view showing the influence of the stress by the stressor film upon the semiconductor substrate with respect to a depth from the surface of the semiconductor substrate;

FIG. 4 is a view showing the influence of the stress by the stressor film upon the semiconductor substrate with respect to the gate height of the transistor;

FIG. 5A is a view showing a process of forming a gate, an extension layer and a pocket layer of an NMOS transistor;

FIG. 5B is a view showing a process of forming the gate, the extension layer and the pocket layer of a PMOS transistor;

FIG. 6A is a view showing a process of forming a sidewall and a first source/drain of the NMOS transistor;

FIG. 6B is a view showing a process of forming the sidewall and the source/drain of the PMOS transistor;

FIG. 7A is a view of the NMOS transistor portion, showing how a hard mask is formed and showing an etching process;

FIG. 7B is a view of the PMOS transistor portion, showing how the hard mask is formed and showing the etching process;

FIG. 8 is a view showing a process of embedding the stressor portion;

FIG. 9A is a view showing the sidewall and a second source/drain of the NMOS transistor;

FIG. 9B is a view showing the sidewall and the second source/drain of the PMOS transistor;

FIG. 10A is a view showing nickel silicide of the NMOS transistor and showing a stressor film forming process;

FIG. 10B is a view showing the nickel silicide of the PMOS transistor and showing the stressor film forming process;

FIG. 11A is a sectional photo of the NMOS transistor.

FIG. 11B is a sectional photo of the PMOS transistor;

FIG. 12A is a view of the NMOS transistor portion, showing how the hard mask is formed and showing the etching process in a second embodiment of the invention;

FIG. 12B is a view of the PMOS transistor portion, showing how the hard mask is formed and showing the etching process in the second embodiment of the invention;

FIG. 13A is a view of the NMOS transistor portion, showing a silicon oxide film forming process;

FIG. 13B is a view of the PMOS transistor portion, showing the silicon oxide film forming process;

FIG. 14A is a view of the NMOS transistor, showing the process of forming the sidewall and the second source/drain;

FIG. 14B is a view of the PMOS transistor, showing the sidewall forming process;

FIG. 15A is a view showing a process of forming the nickel silicide and the stressor film of the NMOS transistor;

FIG. 15B is a view showing a process of forming the nickel silicide and the stressor film of the PMOS transistor.

### DETAILED DESCRIPTION OF THE INVENTION

A best mode (which will hereinafter be termed an embodiment) for carrying out the invention will hereinafter be described with reference to the drawings. Configurations in the following embodiments are exemplifications, and the invention is not limited to the configurations in the embodiments.

### <<Substance of the Invention>>

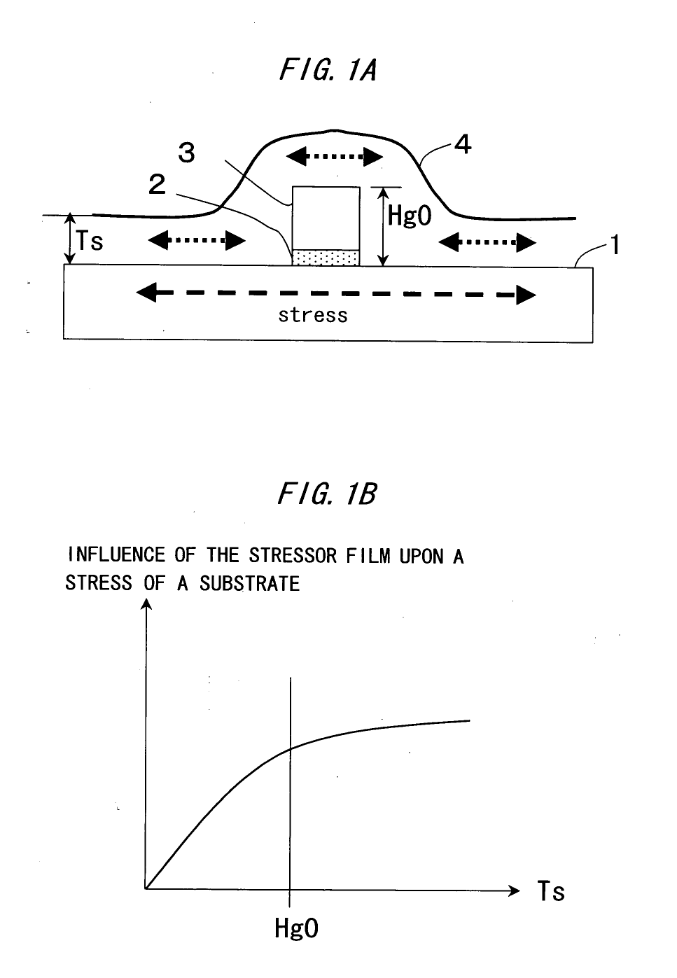

A substance of the embodiment according to the invention will hereinafter be explained with reference to the drawings in FIGS. 1A through 4. FIG. 1A is an explanatory diagram showing a film thickness of a stressor film and a gate height in section of a semiconductor device, and FIG. 1B is a diagram showing a relationship between influence of the stressor film upon a stress occurred on a substrate and the gate height.

In the embodiment, the influence from the stressor film upon the stresses applied on an NMOS transistor (corresponding to a first field effect transistor according to the invention) and a PMOS transistor (corresponding to a second field effect transistor according to the invention) is controlled by controlling the respective gate heights mainly of the NMOS transistor and the PMOS transistor.

FIG. 1A is a conceptual diagram showing a case of forming a gate oxide film 2, a gate 3 and a stressor film 4 on a semiconductor substrate 1. Now, as shown in FIG. 1, let Hg0 be a height of the gate 3 (which is a height including the gate oxide film 2) from the surface of the semiconductor substrate 1. A semiconductor device including this type of gate 3 is covered with the stressor film 4, and a film thickness thereof is set to Ts.

FIG. 1B is a graphic chart showing influence of the stressor film 4 upon the semiconductor substrate 1 in the semiconductor device modeled in FIG. 1A. Herein, the influence of the stressor film 4 upon the semiconductor substrate 1 can be defined as a value given by dividing a stress occurred on the semiconductor substrate 1 by a stress occurred on the stressor film 4 (semiconductor substrate 1's stress/stressor film 4's stress).

As shown in FIG. 1B, the influence of the stressor film 4 changes according to the film thickness Ts of the stressor film 4. In particular, what is understood from FIG. 1B is that till the film thickness Ts of the stressor film 4 exceeds the height Hg0 of the gate 3, the influence of the stressor film 4 augments as the film thickness Ts of the stressor film 4 increases. When the film thickness Ts of the stressor film 4 increases over the height Hg0 of the gate 3, however, the influence of the stressor film 4 becomes smaller than till the film thickness Ts exceeds the height Hg0 of the gate 3. Then, even when the film thickness Ts of the stressor film 4 further increases, it does not happen that the influence of the stressor film 4 greatly augments.

It can be presumed from this result that the respective stresses of the NMOS transistor and the PMOS transistor can take different values even in the case of forming the stressor films 4 each having substantially the same film thickness individually on the NMOS transistor and the PMOS transistor by controlling the gate height of each of the NMOS transistor and the PMOS transistor.

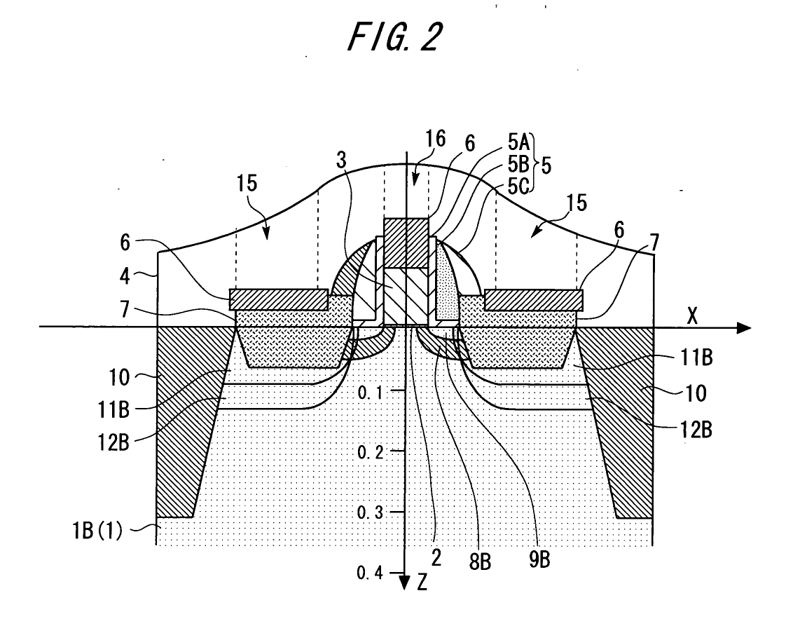

FIG. 2 is a view showing a PMOS transistor portion of a CMOS semiconductor device according to the embodiment. This PMOS transistor portion includes an element separation area 10 that separates this PMOS transistor portion form one other semiconductor element portion (PMOS or NMOS), an N-well 1B formed in the semiconductor substrate 1 in the way of being surrounded by the element separation area 10, a gate insulating film 2 formed on the N-well 1B, the gate 3 formed on the gate insulating film 2, a sidewall 5 formed outside an external wall of the gate 3, a P-type extension layer 9B formed under the sidewall 5, an N-type pocket layer 8B covering the P-type extension layer 9B and formed extending from under the P-type extension layer 9B to the gate oxide film 2, a first source/drain 11B formed in the N-well 1B in a way that extends from the P-type extension layer 9B in an outer direction with respect to the gate 3, a second source/drain 12B formed under the first source/drain 11B, a stressor portion 7 formed after etching part of the first source/drain 11B, a silicon/nickel mixed portion (which will hereinafter be simply termed a NiSi portion) 6 formed above the stressor portion 7 and the gate 3, and the stressor film 4 covering the upper layer of the CMOS semiconductor device (the PMOS transistor in FIG. 2). Note that the silicon/nickel mixed portion is also called a nickel silicide.

In the embodiment, the semiconductor substrate 1 involves using a silicon substrate. Further, a silicon nitride film (SiN) is employed as the stressor film 4. In a case where the stressor film 4 is composed of a silicon nitride film, when the film is formed by plasma CVD (Chemical Vapor Deposition), depending on conditions such as high frequency electric power, a film forming pressure and a gas flow rate when generating plasma, it is possible to control which stress, a tensile stress (a stress acting to stretch in an intra plane direction where the film extends) or a compressive stress (a stress acting to contract in the intra plane direction where the film extends) occurs in the stressor film 4. On the other hand, when forming the film by thermal CVD, the compressive stress occurs in the stressor film 4.

Note that a hole 15 is, as shown in FIG. 2, formed above the first source/drain 11B of the stressor film 4. This hole 15 is used for connecting the first source/drain 11B (and a second source/drain 12B) to an unillustrated wiring layer disposed above the first source/drain 11B. Further, a hole 16 is provided above the gate 3. This hole 16 is employed for connecting the gate 3 to an unillustrated wiring layer disposed above the gate 3.

Moreover, the stressor portion 7 involves using silicon germanium (SiGe). When the stressor portion 7 is composed of the silicon germanium, the stressor portion 7 itself expands, and hence the compressive stress occurs in a portion surrounded by the stressor portion 7. Namely, the germanium has a larger grating constant than the silicon has, so that the silicon germanium mixed with the germanium has a greater inter-grating distance than the silicon has. The inter-grating distance is determined by a germanium-to-silicon ratio. When the silicon germanium is embedded back into a recessed portion by epitaxial growth, distortion occurs in the silicon in the vicinity of interface of the recessed portion, with the result that its influence is propagated to a channel portion and the compressive stress occurs.

Furthermore, in the CMOS semiconductor device in the embodiment, the NMOS transistor portion has substantially the same configuration as in FIG. 2 except a point of providing none of the stressor portion 7 as compared with the PMOS transistor portion in FIG. 2. In the NMOS transistor portion, however, the P type and the N type are reversed in comparison with the PMOS transistor portion in FIG. 2.

In FIG. 2, the X-axis is defined in the intra plane direction parallel to the semiconductor substrate 1. Further, the Z-axis is defined in a downward direction of the semiconductor substrate 1, perpendicularly to the X-axis. The X-axis and the X-axis are defined likewise with respect to the NMOS transistor.

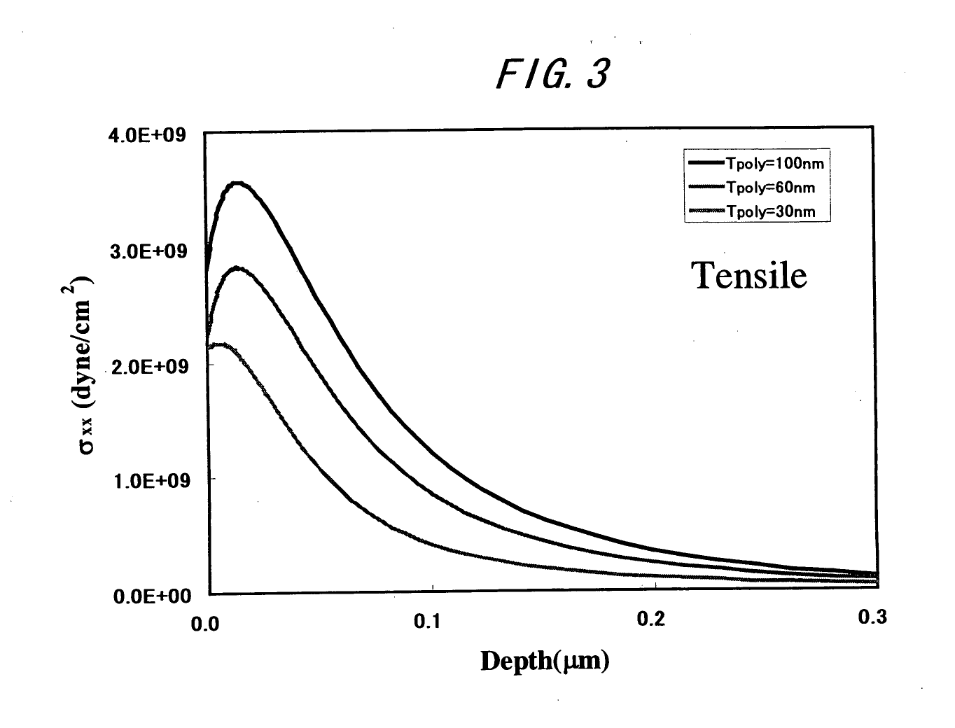

FIG. 3 is a graphic chart showing a distribution of the stress in a depthwise direction (the Z-axis direction) of the semiconductor substrate 1 when a film (PMD layer) having a tensile stress (a stress acting in the direction of stretching in the Z-axis direction) that is 1.5 GPa/nm and a thickness that is 100 nm, is formed as the stressor film 4, where a PMD (PreMetal Dielectric) layer represents a inter bulk layer dielectric film.

This stress distribution is a result of simulation by a finite element method, wherein an interface condition is set on the surface of the semiconductor substrate 1 on the assumption that the stressor film 4 having the stress on the order of 1.5 GPa/nm is formed on the semiconductor substrate 1 illustrated in FIG. 2 while being in contact with this substrate 1. In the simulation, however, the finite element method is applied with a simplified configuration including the gate 3 and the semiconductor substrate 1 in the components in FIG. 2.

The axis of abscissa in FIG. 3 corresponds to a depth shown along the Z-axis in FIG. 2. Namely, FIG. 3 shows the distribution of the stress (dyne/square centimeter) in the depthwise direction. Further, this simulation is executed on the stressor films 4 having three types of film thicknesses, wherein linear graphs corresponding to the respective film thicknesses (100 nm, 60 nm and 30 nm) are depicted.

As shown in FIG. 3, in each of the stressor films 4 having the respective film thicknesses, it is understood that a large stress occurs in an area having a depth that is ten and several nanometers through several tens of nanometers from the surface (Z=0) of the semiconductor substrate 1. It is to be noted that in the result of the simulation in FIG. 3, a film with the tensile stress occurred is set as the stressor film 4, however, the same result is acquired also from the stressor film with the compressive stress occurred. Accordingly, the stress is made to occur in the vicinity of the channel of the MOS transistor by covering the surface of the semiconductor device with the stressor film 4, whereby a mobility of carriers can, it is understood, be improved.

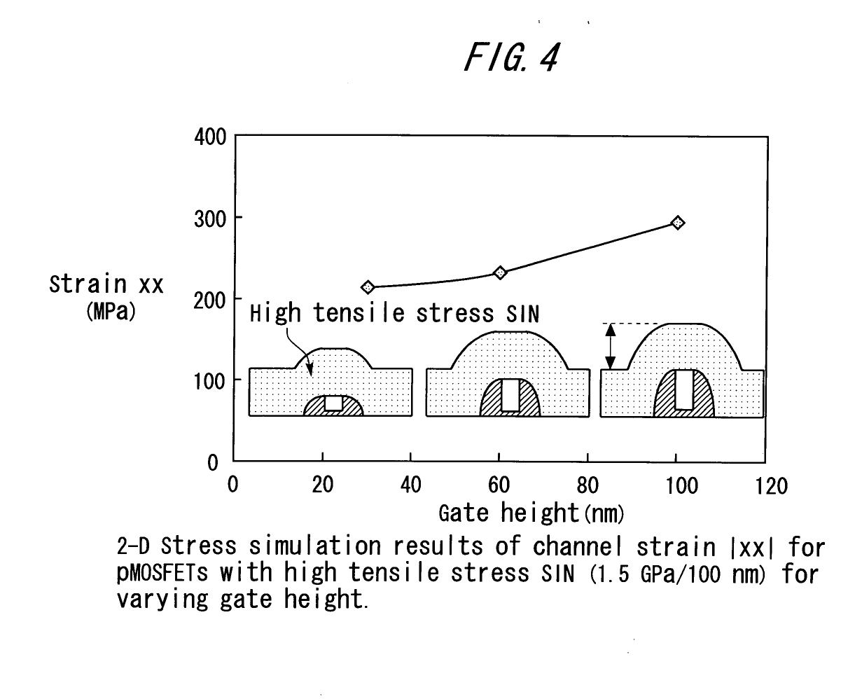

FIG. 4 shows a result of the simulation in the case of changing the gate height Hg0 in the configuration in FIG. 2. In this simulation also, in the structure including the gate 3 and the semiconductor substrate 1, the stress of the stressor film 4 classified as a silicon nitride film is set to 1.5 GPa, and the film thickness is set to 100 nm. Then, a peak value (a peak value in the vicinity of Z=15 nm, where Z is the depth of the semiconductor substrate 1) of the stress is calculated in a way that changes the gate height Hg0.

As illustrated in FIG. 4, when the height Hg0 of the gate 3 decreases from 100 nm down to 60 nm, the stress of the semiconductor substrate 1 greatly reduces from 300 MPa down to approximately 220 MPa. Even when the height Hg0 of the gate 3 further decreases from 60 nm, however, a degree of the drop in the stress of the semiconductor substrate 1 is lowered.

Accordingly, as understood from FIG. 1, an effect of applying the stress to the semiconductor substrate 1 is reduced even when the film thickness of the stressor film 4 is increased over the gate height Hg0. On the other hand, as comprehended from FIG. 4, in such a case that the film thickness of the stressor film 4 is on the order of 100 nm, even when the gate height is further decreased from about 60 nm, the degree of the drop in the influence of applying the stress to the semiconductor substrate 1 becomes moderate.

### <<First Embodiment>>

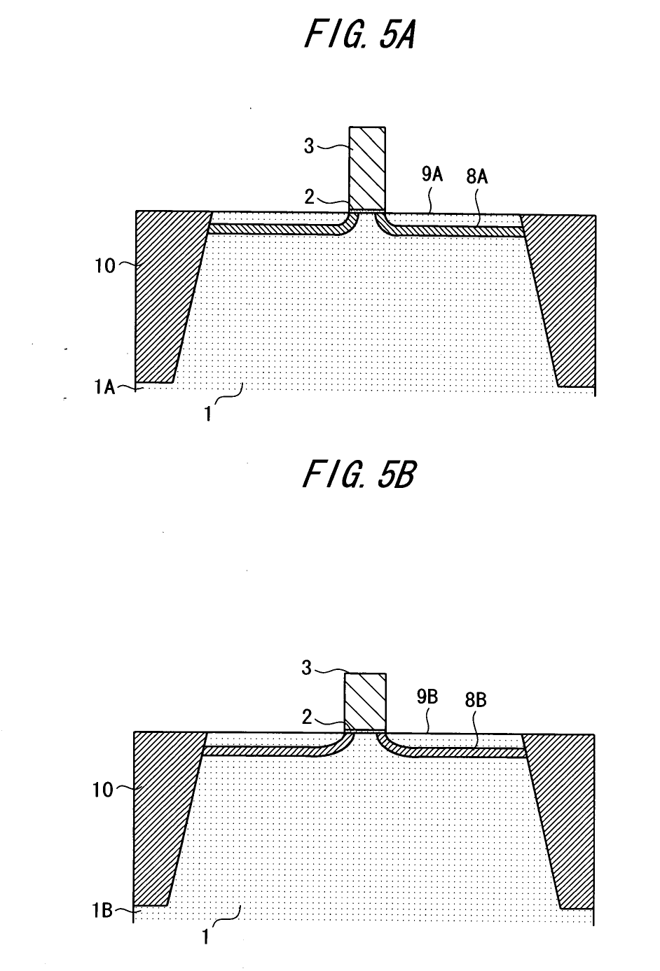

A method of manufacturing the CMOS semiconductor device according to a first embodiment of the invention will hereinafter be described with reference to FIGS. 5A through 11B. In the first embodiment, FIGS. nA (n=5 through 11) show sections of the NMOS transistor portions, and FIGS. nB (n=5 through 11) illustrate sections of the PMOS transistor portions. Further, in the following discussion, an assumption is that a P-type substrate area (P-well) 1A and an N-type substrate area (N-well) 1B will have already been formed by ion implantation etc.

As illustrated in FIGS. 5A (and 5B), to begin with, the element separation area 10 is formed in the P-well 1A (and N-well 1B). The element separation area 10 is formed by a known process, e.g., a LOCOS (Local Oxidation of Silicon) method. After forming the element separation area 10, the gate oxide film 2 is formed on the surface of the semiconductor substrate 1 (the gate oxide film 2 (FIG. 5A) of the NMOS transistor corresponds to a first insulating layer according to the invention, and the gate oxide film 2 (FIG. 5B) of the PMOS transistor corresponds to a second insulation layer according to the invention). After forming the gate oxide film 2, a channel ion may be implanted for adjusting a threshold value.

Next, the gate 3 is formed of, e.g., polysilicon(polycrystalline silicon) by a known process on the semiconductor substrate 1. Herein, for example, after the polysilicon has been formed (deposited) on the substrate surface by the CVD method etc, a photoresist is coated, and the photoresist excluding the area of the gate 3 is removed. Then, the area of the gate 3 is protected by the photoresist, and an area other than the area of the gate 3 is etched. In the first embodiment, at this point of time the film thickness of the gate 3 is on the order of 100 nm.

Next, as shown in FIG. 5A, an N-type extension layer 9A and a P-type pocket layer 8A are formed in the NMOS transistor portion (the P-well 1A portion). The N-type extension layer 9A is formed by implanting, e.g., an impurity such as arsenic (or phosphorous) (herein, the arsenic is used with an energy of 1.0 Kev and with a dose of 1×10¹⁵). Further, the P-type pocket layer 8A is formed by implanting the impurity such as boron (or indium) (herein, the indium is used with an energy of 50 Kev and with a dose of 4×10¹³).

As shown in FIG. 5B, a P-type extension layer 9B and an N-type pocket layer 8B are formed in the same procedure in the PMOS transistor portion (the N-well 1B portion).

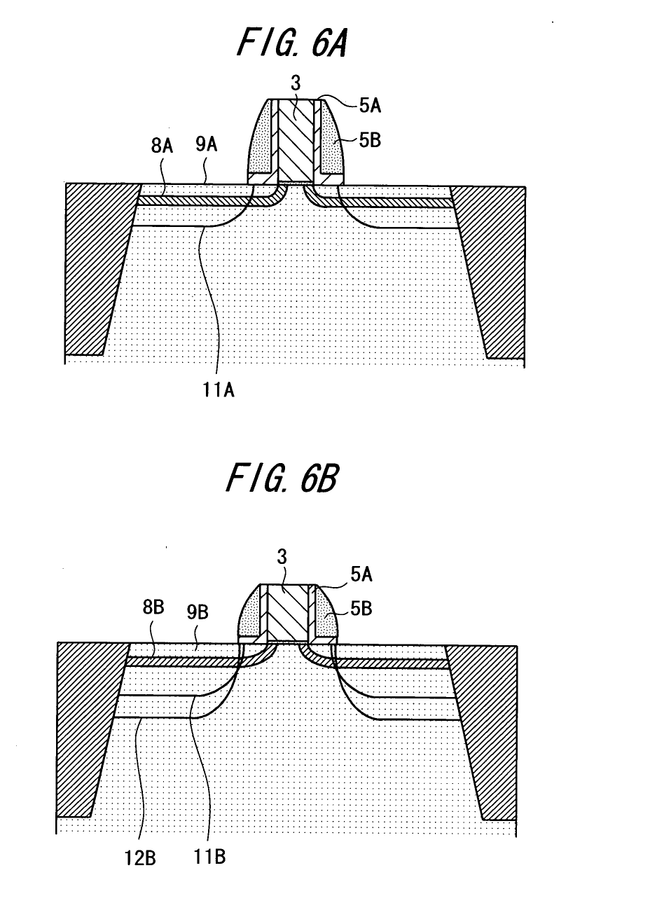

Next, as illustrated in FIGS. 6A and 6B, a silicon oxide film 5A and a silicon nitride film 5B are formed along the external wall portion of the gate 3. The silicon oxide film 5A and the silicon nitride film 5B configure the sidewall 5.

Each of these films can be formed by covering the entire substrate surface with the silicon oxide film 5A and further with the silicon nitride film 5B in the known procedure that is, e.g., the thermal CVD method and thereafter anisotropically etching the sidewall 5 in a way that uses RIE (Reactive Ion Etching).

Next, as shown in FIG. 6A, an N-type first source/drain 11A is formed in the NMOS transistor portion by the ion implantation. Further, as illustrated in FIG. 6B, the P-type first source/drain 11B is formed in the PMOS transistor portion by the ion implantation. Moreover, the P-type second source/drain 12B is formed by the ion implantation.

In the formation of the N-type first source/drain 11A, at first, the area excluding the N-type first source/drain 11A is masked with the photoresist. Then, the arsenic as the impurity is implanted with an energy of 10 KeV and with a dose of 1×10¹⁵, thereby forming the N-type first source/drain 11A.

Moreover, in the formation of the P-type first source/drain 11B, the area excluding the P-type first source/drain 11B is masked with the photoresist. Then, the boron as the impurity is implanted with the energy of 6 KeV and with the dose of 1×10¹³, thereby forming the P-type first source/drain 11B. Furthermore, the P-type second source/drain 12B is formed by implanting, e.g., the boron as the impurity with the energy of 10 KeV and with the dose of 1×10¹³.

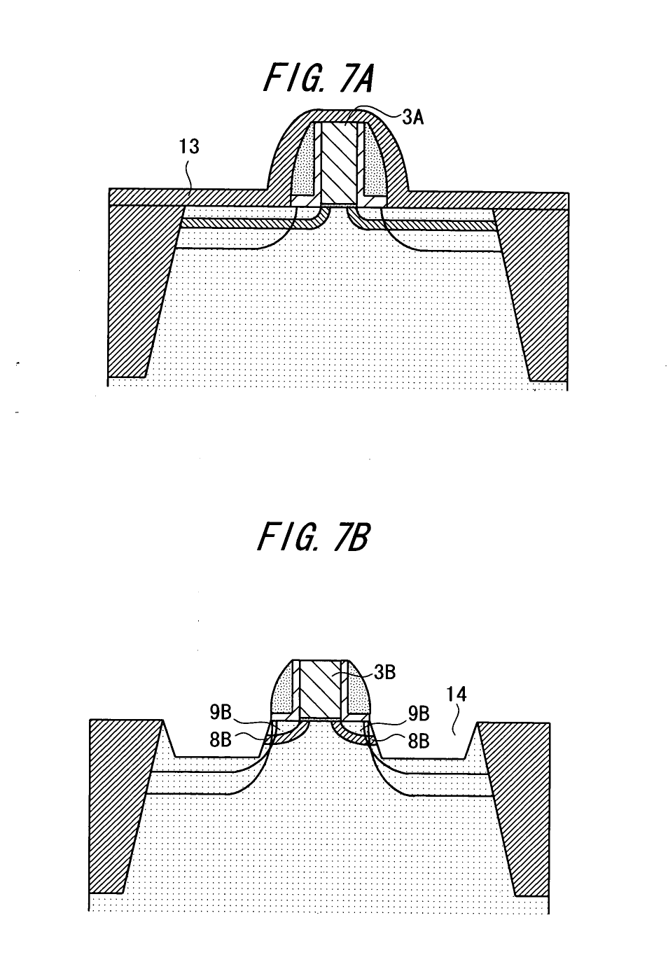

Next, as shown in FIG. 7A, the silicon oxide film is deposited (a film growth temperature is set at 550° C. or under) by the CVD method so as to cover the whole of the semiconductor substrate 1, thereby forming a hard mask 13. Further, the PMOS transistor portion is provided with a window formed with a pattern by the photoresist, and the hard mask 13 is etched off. Then, the P-type first source/drain 11B and the gate 3 of the PMOS transistor are etched.

As a result, a recessed portion 14 is formed in the area of the P-type first source/drain 11B. A depth of the recessed portion from the surface of the semiconductor substrate 1 is on the order of 50 nm. Moreover, as a result of the etching described above, a height of a gate 3B of the PMOS transistor decreases under a height of a gate 3A of the NMOS transistor (in the case of identically designating the gate 3 of the NMOS transistor and the gate 3 of the PMOS transistor, these gates shall hereinafter be called the gate 3A (corresponding to a first gate electrode according to the invention) and the gate 3B (corresponding to a second gate electrode according to the invention), respectively)). In the first embodiment, the gate 3B of the PMOS transistor is etched to approximately 50 nm, and a height of the gate 3B from the surface of the semiconductor substrate 1 is on the order of 50 nm.

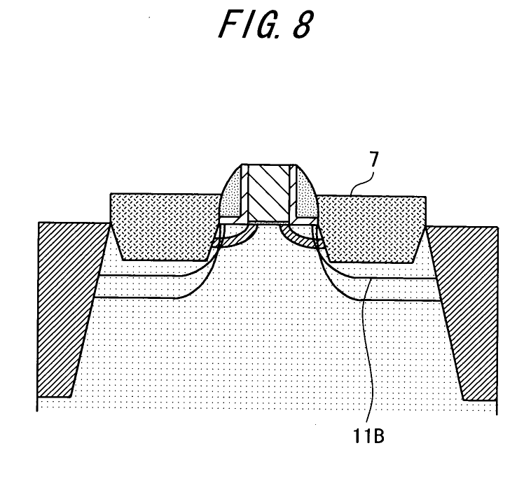

Next, as shown in FIG. 8, the stressor portion 7 is embedded into the recessed portion 14 in the area of the P-type first source/drain 11B. The stressor portion 7 is formed of silicon germanium. A forming procedure is as follows. The surface of the recessed portion 14 is cleaned by a hydrofluoric acid treatment for etching off the thermal oxide film to 2 nm, and thereafter the silicon germanium containing the boron is gown by an epitaxial growth method, thus completely embedding it back. If possible, there is to be provided a swelling of 10 nm or greater from the interface between the gate insulating film and the silicon substrate.

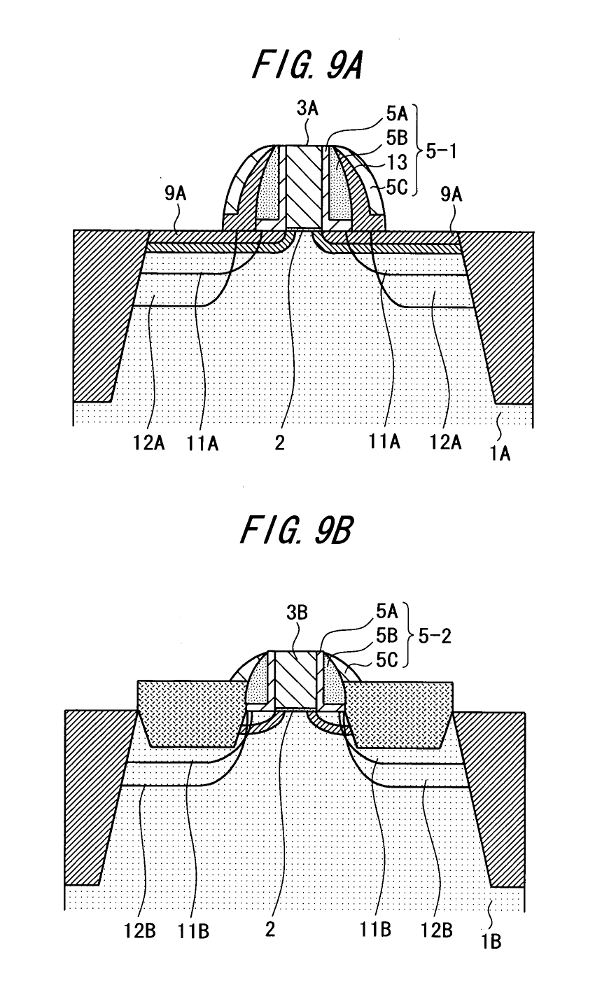

Next, as illustrated in FIG. 9A, a silicon oxide film 5C is formed outside the sidewall 5 (the silicon nitride film 5B) in the known procedure. To be specific, after covering the surface of the semiconductor substrate 1 with the silicon oxide film 5C, a portion including the gate 3 and the sidewall 5 is masked with the photoresist, and the portion excluding the gate 3 and the sidewall 5 is anisotropically etched. Through this procedure, the silicon oxide film 5A, the silicon nitride film 5B and the silicon oxide film 5C (and a layer of the hard mask 13 inclusive) configure the sidewall 5 (5-1) of the NMOS transistor (see FIG. 9A). A thickness of the sidewall 5-1 of the NMOS transistor is on the order of 70 nm at the maximum.

Further, as illustrated in FIG. 9B, the silicon oxide film 5A, the silicon nitride film 5B and the silicon oxide film 5C configure the sidewall 5 (5-2) of the PMOS transistor. A thickness of the sidewall 5-2 of the PMOS transistor is on the order of 70 nm at the maximum. Note that the sidewall 5-1 of the NMOS transistor and the sidewall 5-2 of the PMOS transistor are herein generically referred to as the sidewall S.

Moreover, for forming the N-type second source/drain 12A shown in FIG. 9A, there is formed a resist pattern in which an area excluding the area of the N-type second source/drain 12A is masked with the photoresist. Then, as shown in FIG. 9A, the N-type second source/drain 12A is formed by the ion implantation, wherein the photoresist (and the sidewall 5) serves as the mask. The N-type second source/drain 12A is formed by implanting, for instance, the phosphorous as the impurity with the energy of 8 KeV and with the dose of 8×10¹⁵.

In the NMOS transistor portion, as illustrated in FIG. 9A, N-type areas each composed of the N-type extension layer 9A, the first source/drain 11A and the second source/drain 12A are provided in two places below the side portion of the gate 3A. One of these N-type areas corresponds to an originating area according to the invention. Further, the other of these N-type areas corresponds to a terminating area according to the invention. Moreover, a lower portion of the gate insulating film 2 of the NMOS transistor corresponds to an area of a first conductive path, and the P-well 1A corresponds to a conductive layer of a second conductive type.

On the other hand, in the PMOS transistor portion, as shown in FIG. 9B, P-type areas each composed of the P-type extension layer 9B, the first source/drain 11B and the second source/drain 12B are provided in two places below the side portion of the gate 3B. One of these P-type areas corresponds to an originating area according to the invention. Further, the other of these P-type areas corresponds to a terminating area according to the invention. Moreover, a lower portion of the gate insulating film 2 of the PMOS transistor corresponds to an area of a second conductive path, and the N-well 1B corresponds to a conductive layer of a first conductive type.

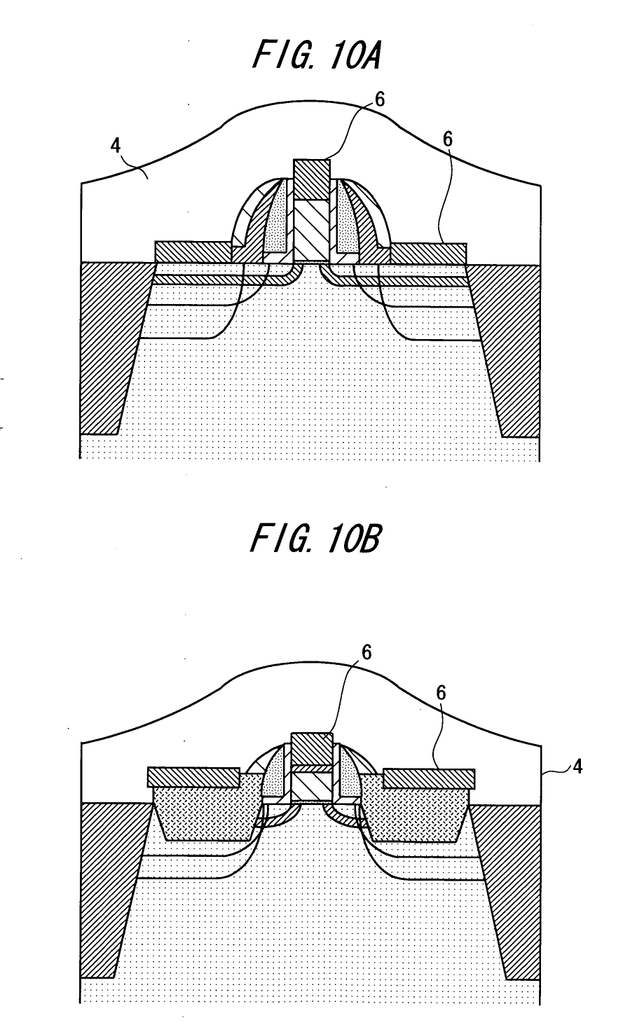

Next, as shown in FIGS. 10A and 10B, the surface of the semiconductor substrate 1 is subjected to sputtering of Ni, and a thermal treatment is conducted thereon, thus forming a NiSi (nickel silicide) portion 6. Further, the stressor film 4 is formed of a silicon nitride film on the surface of the semiconductor substrate 1 by the plasma CVD. The stressor film 4 is provided with holes 15, 16 for connecting the gate 3 and the first source/drain (and the second source/drain) respectively to the upper wiring layers (see FIG. 2).

When the stressor film 4 is formed by the plasma CVD, it is possible to control which stress, the tensile stress or the compressive stress, occurs in the stressor film 4 after being grown, depending on the conditions such as the high frequency electric power, the film forming pressure and the gas flow rate that are inputted when generating the plasma.

For instance, the tensile stress can be made to occur under the conditions including a process of eliminating, after the film has grown in an extremely rarefied atmosphere of the material gas (e.g., SiH₄:NH₃=1:8 or larger) while flowing nitrogen as a diluent gas at a large flow rate, hydrogen contained in the film by irradiating the plasma etc. This is attributed, it is considered, to the elimination of the hydrogen. Further, the compressive stress can be made to occur under the condition such as tetramethylsilane: NH₃=1:6 or larger while flowing the nitrogen as the diluent gas at the large flow rate. This is derived, it is considered, from decreasing a carbon composition ratio. Note that when the stressor film is formed by the thermal CVD, the compressive stress occurs in the stressor film 4 after the film has grown. This is, it is considered, because of a small residual quantity of residual halogen elements typified by the hydrogen in the silicon nitride film due to its elimination and because of a difference in thermal expansion coefficient of the stressor film 4 from the silicon substrate due to the heat at the film growth time.

Accordingly, as in the first embodiment, when etching so that the gate height in the PMOS transistor portion is lower than the gate height in the NMOS transistor portion (see FIGS. 7A and 7B), it is feasible to control so that the influence by the stressor film 4 in the PMOS transistor becomes smaller than in the NMOS transistor. Hence, when the tensile stress is made to occur in the stressor film 4, this affects the semiconductor substrate 1 that forms the NMOS transistor portion, and the tensile stress occurs also in NMOS transistor. As a result, the mobility of electrons in the NMOS transistor can be improved.

On the other hand, the influence of the tensile stress occurred in the stressor film 4 is, it follows, reduced with respect to the silicon substrate configuring the PMOS transistor portion. Accordingly, an effect due to the compressive stress occurred by the stressor portion 7 (silicon germanium portion) embedded into the recessed portion 14 in the area of the P-type first source/drain 11B, can be made by far greater than an effect of the tensile stress occurred by the stressor film 4. As a result, the hole mobility of the PMOS transistor can be also improved.

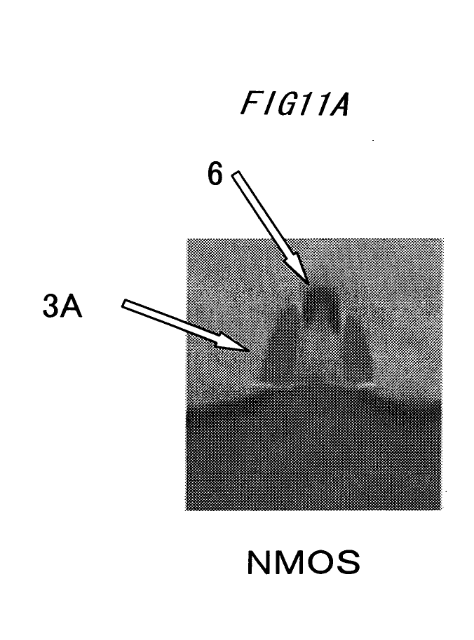

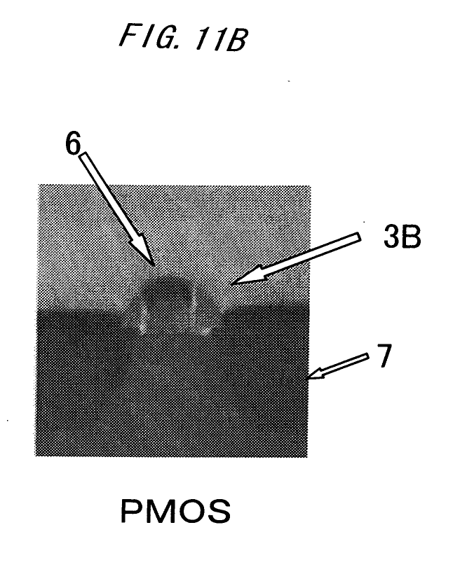

FIG. 11A shows a photo in section (enlarged by a scan type electron microscope) of the NMOS transistor in the first embodiment. FIG. 11A shows the photo at a point of time when completing the process shown in FIG. 10A. Further, FIG. 11B shows a photo in section of the PMOS transistor. FIG. 11B shows the photo at a point of time when completing the process shown in FIG. 10B. As obvious from these photos, in the process explained in the first embodiment, the gate 3B of the PMOS transistor is formed smaller than the gate 3A of the NMOS transistor.

As discussed above, according to the semiconductor device in the first embodiment, in the case of forming the film serving as the stressor film 4 with the tensile stress occurred, the electron mobility in the NMOS transistor can be improved. Further, after reducing the tensile stress in the stressor film 4 of the PMOS transistor, it is possible to acquire the effect of the compressive stress caused by the stressor portion 7. It is therefore feasible to further improve the hole mobility of the PMOS transistor.

<Modified Example>

In the first embodiment, the stressor film 4 involves using the silicon nitride film, and the tensile stress is made to occur by controlling the process conditions (the high frequency electric power, the film forming pressure, the gas flow rate, etc) at the film growth time based on the plasma CVD. Then, the influence of the stressor film 4 is augmented by setting the height of the gate 3A of the NMOS transistor larger than the height of the gate 3B of the PMOS transistor, thus intensifying the tensile stress occurred in the NMOS transistor. On the other hand, the influence of the stressor film 4 is diminished by setting the height of the gate 3B of the PMOS transistor smaller than the height of the gate 3A of the NMOS transistor, thus reducing the tensile stress occurred in the PMOS transistor.

Moreover, the stressor portion 7 embedded into the source/drain portion of the PMOS transistor involves employing the silicon germanium, and the compressive stress is made to occur in the vicinity of the channel sandwiched in between the stressor portion 7 and the stressor portion 7.

In place of this, however, the stressor film 4 may involve using the silicon nitride film, and the compressive stress may be made to occur in a way that likewise controls the process conditions (the high frequency electric power, the gas flow rate, etc) at the film growth time based on the plasma CVD. Further, the compressive stress may be made to occur in the stressor film 4 by forming the silicon nitride film with the thermal CVD.

Then, after keeping the compressive stress occurred in the PMOS transistor by setting the height of the gate 3A of the NMOS transistor smaller than the height of the gate 3B of the PMOS transistor, the compressive stress occurred in the NMOS transistor may also be weakened by diminishing the influence of the stressor film 4 upon the NMOS transistor.

Still further, SiC (silicon carbide) may also be embedded as the stressor portion 7 into the source/drain portion of the NMOS transistor. To be specific, with the same configuration as the configuration shown in FIG. 2, the silicon carbide is used as the stressor portion 7, thereby enabling the occurrence of the tensile stress in the vicinity of the channel surrounded by the silicon carbide. Namely, the carbon has a smaller grating constant than the silicon has, and hence the silicon carbide mixed with the carbon becomes narrower in the inter-grating distance than the silicon. The inter-grating distance is determined by a carbon-to-silicon ratio. When the silicon carbide is embedded back into the recessed portion by the epitaxial growth, distortion appears in the silicon in the vicinity of the interface of the recessed portion, with the result that the tensile stress occurs in the channel portion due to its influence.

With such a configuration, there is the stress characteristic absolutely reversed to that in the first embodiment, i.e., the characteristic is that the stressor film 4 effectively causes the compressive stress in the PMOS transistor, while the influence of the compressive stress by the stressor film 4 upon the NMOS transistor can be reduced. Further, the stressor portion 7 can make the tensile stress effectively occur in the NMOS transistor. A manufacturing process in this case is substantially the same as the process in FIGS. 5A through 10B.

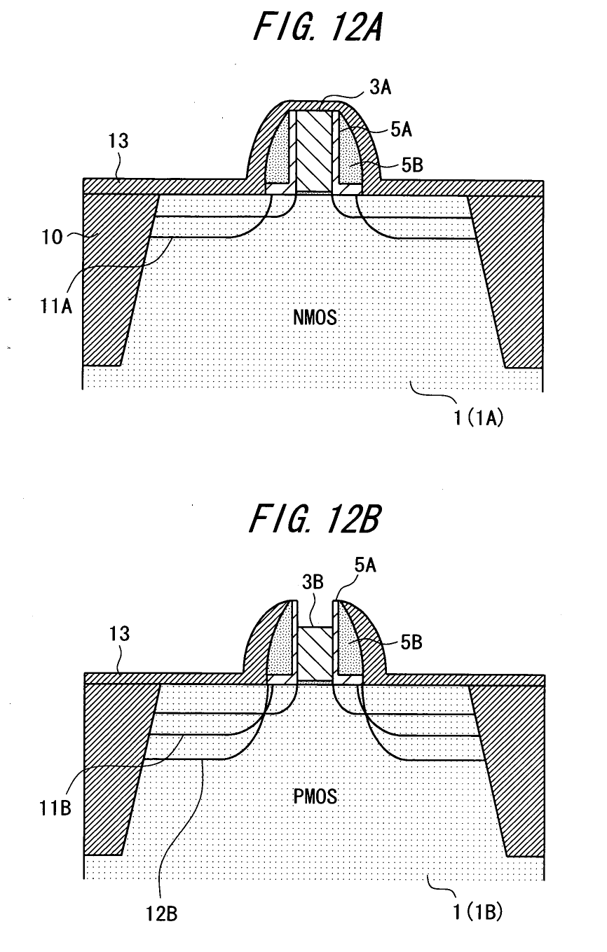

A second embodiment of the invention will hereinafter be described with reference to the drawings in FIGS. 12A through 15B. In the first embodiment, the film with the tensile stress occurred is formed as the stressor film 4 by decreasing the height of the gate 3 of the PMOS transistor. Further, the stressor portion 7 composed of the silicon germanium is embedded into the recessed portion 14 in the area of the P-type first source/drain 11B, thereby controlling the stress occurred in the PMOS transistor.

Moreover, in the modified example thereof, the film with the compressive stress occurred is formed as the stressor film 4 by decreasing the height of the gate 3 of the NMOS transistor. Still further, the stressor portion 7 composed of the silicon carbide is embedded into the recessed portion 14 in the area of the N-type first source/drain 11A, thereby controlling the stress occurred in the NMOS transistor.

The second embodiment will deal with a semiconductor device including neither the recessed portion 14 in the area of the P-type first source/drain 11B nor the stressor portion 7. Other configurations and operations are the same as those in the case of the first embodiment. Such being the case, the same components are marked with the same numerals and symbols, and their explanations are omitted. To be specific, in the second embodiment also, in the same way as in FIGS. 5A through 6B in the first embodiment, the silicon substrate is provided with the element separation area 10, the gate 3, the extension layer, the pocket layer, the silicon oxide film 5A, the silicon nitride film 5B, the N-type first source/drain 11A, the P-type first source/drain 11B and the P-type second source/drain 12B. Note that in FIGS. 12A through 15B in the second embodiment, the extension layer and the pocket layer are illustrated as those simplified.

Next, as illustrated in FIGS. 12A and 12B, the silicon oxide film is deposited by use of the CVD method so as to cover the whole of the semiconductor substrate 1, whereby the hard mask 13 is formed of the silicon oxide film. Further, a portion of the gate 3B of the PMOS transistor is provided with a window formed with a pattern by the photoresist, and the gate 3B is exposed by etching the hard mask 13. Then, the gate 3B of the PMOS transistor is etched (in this case, unlike FIG. 7B, the P-type first source/drain 11B is protected by the hard mask 13).

As a result, the height of the gate 3B of the PMOS transistor becomes smaller than the height of the gate 3A of the NMOS transistor.

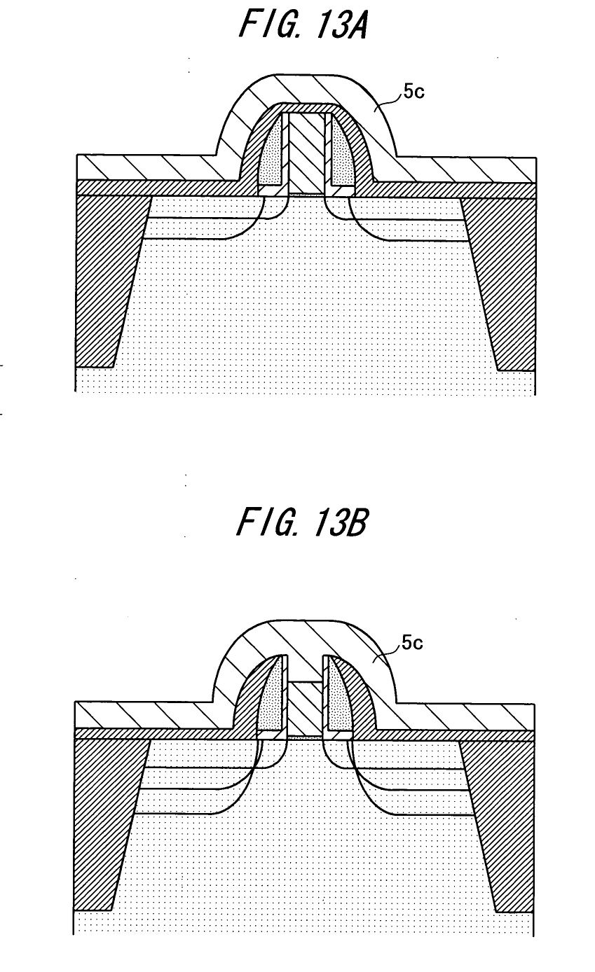

Next, as shown in FIGS. 13A and 13B, the surface of the semiconductor substrate 1 is subsequently covered with the silicon oxide film 5C (or the silicon nitride film 5B).

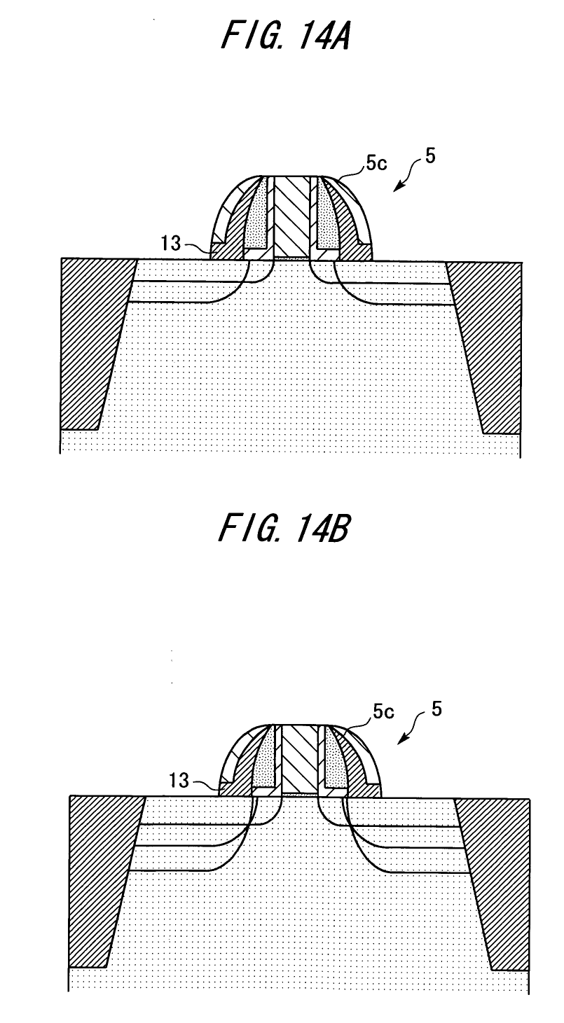

Next, as shown in FIGS. 14A and 14B, a portion excluding the gate 3 covered with the silicon oxide film 5C is anisotropically etched, thereby forming the sidewall 5. Then, in the same way as in the first embodiment, the portion excluding the N-type second source/drain 12A is masked with the resist pattern.

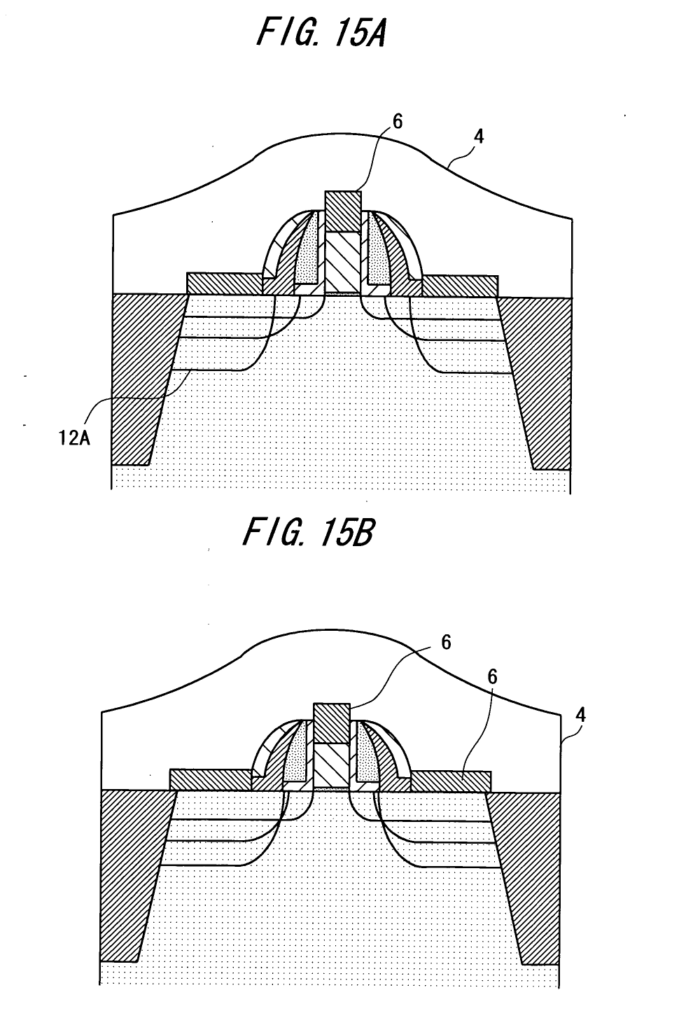

Moreover, in the same manner as in the first embodiment, as illustrated in FIG. 15A, the N-type second source/drain 12A is formed by the ion implantation, wherein the resist pattern (and the sidewall 5) serves as the mask.

Yet further, as shown in FIGS. 15A and 15B, in the same manner as in the first embodiment, the NiSi portion 6 is formed, and, moreover, the surface of the semiconductor substrate 1 is formed with the stressor film 4 using the silicon nitride film by the plasma CVD.

As discussed above, according to the semiconductor device in the second embodiment, in the case where the film with the tensile stress occurred is formed as the stressor film 4, the electron mobility in the NMOS transistor can be improved. Further, the influence by the stressor film 4 upon the PMOS transistor is reduced by decreasing the height of the gate 3B of the PMOS transistor, whereby the tensile stress can be reduced. Accordingly, the decrease in the hole mobility of the PMOS transistor can be restrained.

<Modified Example>

The second embodiment has dealt with the semiconductor device in which the film with the tensile stress occurred is formed as the stressor film 4 by decreasing the height of the gate 3B of the PMOS transistor. The second embodiment has dealt specifically with the semiconductor device having none of the stressor portion in the recessed portion 14 in the area of the P-type first source/drain 11B. As a substitute for this configuration, there may be configured a semiconductor device in which the film with the compressive stress occurred is formed as the stressor film 4 by decreasing the height of the gate 3A of the NMOS transistor. Namely, in the configuration explained in the modified example of the first embodiment, there may also be configured a semiconductor device including none of the stressor portion 7 in the recessed portion 14 in the area of the N-type first source/drain 11A.

With such a configuration, when the film with the compressive stress occurred is formed as the stressor film 4, the hole mobility in the PMOS transistor can be improved. Further, the influence of the stressor film 4 upon the semiconductor substrate 1 is diminished by decreasing the height of the gate 3A of the NMOS transistor, whereby the compressive stress can be reduced. Hence, the decrease in the electron mobility of the NMOS transistor can be restrained.

<Others>

The disclosures of Japanese patent application No. JP2005-349490 filed on Dec. 2, 2005 including the specification, drawings and abstract are incorporated herein by reference.

What is claimed is:

1. A semiconductor device including a first field effect type transistor of a first conductivity type and a second field effect type transistor of a second conductivity type that are provided on a semiconductor substrate,
the first field effect type transistor comprising:
a first gate electrode;
a first insulating layer under the first gate electrode;
a conductive layer of the second conductivity type for forming a first conductive path of the first conductivity type under the first insulating layer;
a first conductivity type originating area that is formed at one end of a second conductivity type area which should become the first conductive path, and that should become an originating point of the first conductive path; and
a first conductivity type terminating area that is formed at the other end of-the second conductivity type area and that should become a terminating point of the first conductive path;
the second field effect type transistor comprising:
a second gate electrode;
a second insulating layer under the second gate electrode;
a conductive layer of the first conductivity type for forming a second conductive path of the second conductivity type under the second insulating layer;
a second conductivity type originating area that is formed at one end of a first conductivity type area which should become the second conductive path, and that should become an originating point of the second conductive path; and
a second conductivity type terminating area that is formed at the other end of the first conductivity type area and that should become a terminating point of the second conductive path,
wherein there is formed a stressor film covering the first field effect transistor and the second field effect transistor, formed with openings from which the originating area and the terminating area of each of the first field effect transistor and the second field effect transistor are partially exposed, and applying a stress to at least an area extending from the vicinity of the originating area to the vicinity of the terminating area of each of the first field effect transistor and the second field effect transistor, and
a height of the first gate electrode in a direction substantially perpendicular to the semiconductor substrate is set different from a height of the second electrode in the direction substantially perpendicular to the semiconductor substrate.

2. The semiconductor device according to claim 1, wherein a difference between the height of the first gate electrode and the height of the second electrode is equal to or larger than about 30% of the height of the first gate electrode.

3. The semiconductor device according to claim 1, wherein the semiconductor substrate is composed mainly of silicon, and the stressor film is composed mainly of silicon nitride.

4. The semiconductor device according to claim 1, wherein the first conductive type is an N-type, the second conductivity type is a P-type, the stressor film has a stretching stress in a direction of stretching within a plane where the stressor film extends, and the height of the first gate electrode is larger than the height of the second gate electrode.

5. The semiconductor device according to claim 4, wherein a stress generating substance other than the silicon, for stressing a portion interposed between the originating area and the terminating area in a shrinking direction, is embedded in the originating area and in the terminating area of the second field effect transistor.

6. The semiconductor device according to claim 5, wherein the semiconductor substrate is composed mainly of silicon, and the stress generating substance is silicon germanium.

7. The semiconductor device according to claims 1, wherein the first conductive type is an N-type, the second conductivity type is a P-type, the stressor film has a compressive stress in a direction of shrinking within a plane where the stressor film extends, and the height of the second gate electrode is larger than the height of the first gate electrode.

8. The semiconductor device according to claim 7, wherein a stress generating substance other than the silicon, for stressing a portion interposed between the originating area and the terminating area in a stretching direction, is embedded in the originating area and in the terminating area of the first field effect transistor.

9. The semiconductor device according to claim 8, wherein the semiconductor substrate is composed mainly of silicon, and the stress generating substance is silicon carbide.

10. A manufacturing method of a semiconductor device including a first field effect type transistor of a first conductivity type and a second field effect type transistor of a second conductivity type that are formed on a semiconductor substrate, the method comprising:
a step of forming an element separation structure on the semiconductor substrate;
a step of forming a first gate electrode of the first field effect transistor and a second gate electrode of the second field effect transistor in areas separated by the element separation structure;
a step of forming an originating area and a terminating area of the first field effect transistor under a side portion of the first gate electrode;
a step of forming an originating area and a terminating area of the second field effect transistor under a side portion of the second gate electrode;
a step of forming an insulating film above the first gate electrode and the second gate electrode;
a pattern forming step of exposing the second gate electrode by etching the insulating film above the second gate electrode;
a height control step of decreasing the gate height by etching the second gate electrode through the opening; and
a step of forming a stressor film covering the first field effect transistor and the second field effect transistor, formed with openings from which the originating area and the terminating area of each of the first field effect transistor and the second field effect transistor are partially exposed, and applying a stress to at least an area extending from the vicinity of the originating area to the vicinity of the terminating area of each of the first field effect transistor and the second field effect transistor, and
a height of the first gate electrode in a direction substantially perpendicular to the semiconductor substrate is set different from a height of the second electrode in the direction substantially perpendicular to the semiconductor substrate.

11. A manufacturing method of a semiconductor device according to claim 10, wherein the pattern forming step includes a step of exposing the originating area and the terminating area of the second field effect transistor,
the height control step includes a step of forming recessed portions by etching the originating area and the terminating area of the second field effect transistor, and
the manufacturing method further comprises a step of embedding stressor portions generating a stress in an area interposed between the recessed portions formed in the originating area and the terminating area of the second field effect transistor, into the recessed portions formed in the originating area and the terminating area of the second field effect transistor.
